(19) United States
(12) Patent Application Publication
(10) Pub. No.: US 2024/0293917 A1
(43) Pub. Date: Sep. 5, 2024

(54) CHUCK FOR ACQUIRING A WARPED WORKPIECE BY AMPLIFIED SUCTION

(71) Applicant: Core Flow Ltd., Daliyat el-Karmel (IL)

(72) Inventor: Oshri IFERGAN, Daliyat al-Carmel (IL)

(73) Assignee: Core Flow Ltd., Daliyat el-Karmel (IL)

(21) Appl. No.: 18/591,281

(22) Filed: Feb. 29, 2024

Related U.S. Application Data
(60) Provisional application No. 63/449,061, filed on Mar. 1, 2023.

(51) Int. Cl. B25B 11/00

(52) U.S. Cl. CPC B25B 11/005

(57) ABSTRACT

A chuck for holding a workpiece, includes one or more first compartments, each defining a first space and having a wall that forms a chuck surface with a plurality of vacuum ports on the chuck surface; a second compartment defining a second space for temporarily maintaining vacuum; one or a plurality of conduits fluidically connecting between the second compartment and each of the one or a plurality of first compartments, each of the conduits having a valve which when opens allows flow through that conduit and when closed prevents flow through that conduit; and a controller, for controlling the valves, wherein vacuum within the second compartment when the valve of each of said one or more conduits is closed is used on the vacuum ports when the valve of each of said one or more conduits is opened.

### CROSS-REFERENCE

The present application claims the benefit of U.S. Provisional Patent Application No. 63/449,061, filed Mar. 1, 2023, incorporated by reference in its entirety.

### FIELD OF THE INVENTION

The present invention relates to chucks for holding a workpiece. More particularly, the present invention relates to a chuck for acquiring a warped workpiece by amplified vacuum suction.

### BACKGROUND OF THE INVENTION

Many types of industrial or other processes require manipulation of various types of workpieces. Typically, a chuck is used to acquire a workpiece, and to manipulate the workpiece for various types of processing. Where the workpiece is sufficiently thin or light, the chuck may operate by applying suction to the workpiece to hold the workpiece at a precisely defined location during processing.

For example, the semiconductor industry typically requires manipulating silicon wafers, e.g., for production of electronic devices. A vacuum chuck may acquire such a wafer, and hold it during such processing as coating, cutting, machining, etching, polishing, inspection, or other processing. In some applications the wafer may be warped, thus requiring strong suction to be applied in order for the vacuum chuck to acquire the wafer.

In some applications there are strict cleanliness requirements for handling the workpiece so any contact of non-metal material with the workpiece is to be avoided. For example, the semiconductor industry typically requires manipulating silicon wafers avoiding any contact with non-metal materials (e.g., usage of rubber nipples for holding the workpiece in place by vacuum is avoided).

### SUMMARY OF THE INVENTION

There is thus provided, in accordance with an embodiment of the invention, a chuck for acquiring and holding a workpiece. The chuck may include one or a plurality of first compartments, each defining a first space and having a wall that forms a chuck surface having a plurality of vacuum ports that are distributed on the chuck surface. The chuck may also include a second compartment defining a second space for internally temporarily accumulating vacuum. The chuck may also include one or a plurality of conduits fluidically connecting between the second compartment and each of said one or a plurality of first compartments, each of said one or a plurality of conduits having a valve which when opened allows flow through that conduit and when closed prevents flow through that conduit. When a vacuum source is fluidically connected to the second compartment and when the valve of each of said one or more conduits is closed vacuum is temporarily accumulated in the second compartment, such that when the valve of each of said one or more conduits is opened, the accumulated vacuum affects suction at the plurality of vacuum ports on the chuck surface to acquire and hold a workpiece.

According to some embodiments of the present invention, the chuck may further include a controller, configured to close the valve of each of said one or more conduits, to cause vacuum to temporarily accumulate in the second compartment, and to open the valve of each of said one or more conduits to acquire and hold a workpiece on the chuck surface.

According to some embodiments of the present invention, said one or a plurality of first compartments comprises a plurality of first compartments.

According to some embodiments of the present invention, the controller is configured to separately control the valves of the plurality of first compartments.

According to some embodiments of the present invention, the first compartments are arranged concentrically.

According to some embodiments of the present invention, the vacuum ports of the first compartments are arranged in concentric strips.

According to some embodiments of the present invention, at least some of the concentric strips are adjacent to one another.

According to some embodiments of the present invention, at least some of the concentric strips are separated by a gap on the chuck surface.

According to some embodiments of the present invention, the second compartment comprises a vacuum connection port, for connecting to an external vacuum source.

According to some embodiments of the present invention, the plurality of vacuum ports is distributed on a peripheral zone of the chuck surface.

According to some embodiments of the present invention, the plurality of vacuum ports is distributed on the chuck surface in one or a plurality of distribution patterns.

According to some embodiments of the present invention, said one or a plurality of first compartments comprises a single compartment.

According to some embodiments of the present invention, the valve of one or more of said one or a plurality of conduits is a three-way valve.

According to some embodiments of the present invention, the three-way valve is configured to be connected to a pressure source to affect pressure force at the vacuum ports to release the workpiece.

According to some embodiments of the present invention, the chuck further includes one or a plurality of protrusions on the chuck surface to prevent direct contact between the workpiece and the chuck surface.

According to some embodiments of the present invention, there is provided a chuck for acquiring and holding a workpiece. The chuck may include a housing comprising: one or a plurality of first compartments, each defining a first space and having a wall that forms a chuck surface having a plurality of vacuum ports that are distributed on the chuck surface; and one or a plurality of vacuum generators for affecting suction in said one or a plurality of first compartments to cause suction at the plurality of vacuum ports on the chuck surface to acquire and hold a workpiece.

According to some embodiments of the present invention, said one or a plurality of vacuum generators comprises one or a plurality of Venturi vacuum generators.

According to some embodiments of the present invention, an exhaust port of each of the one or a plurality of Venturi vacuum generators is connected to a vacuum source.

According to some embodiments of the present invention, the chuck further includes a controller for controlling a blow of high-pressure through said one or a plurality of Venturi vacuum generators.

According to some embodiments of the present invention, the chuck further includes a controller for controlling a blow of high-pressure through said one or a plurality of Venturi vacuum generators.

According to some embodiments of the present invention, the chuck further includes a controller for controlling the operation of the one or a plurality of vacuum generators.

### BRIEF DESCRIPTION OF THE DRAWINGS

In order for the present invention to be better understood and for its practical applications to be appreciated, the following Figures are provided and referenced hereafter. It should be noted that the Figures are given as examples only and in no way limit the scope of the invention.

Like components are denoted by like reference numerals.

FIG. 1 schematically shows a cross section of a chuck for acquiring a warped workpiece by amplified vacuum suction, according to some embodiments of the present invention, configured for acquiring and flattening a warped workpiece.

FIG. 2A schematically illustrates an isometric view of a chuck for acquiring a warped workpiece by amplified vacuum suction, according to some embodiments of the present invention, configured for acquiring and flattening a warped workpiece.

FIG. 2B shows a part of the chuck shown in FIG. 2A, detailing a three-way valve for use for the operation of an internal compartment for temporarily accumulating vacuum of the chuck.

FIG. 3 is a schematic bottom view of the chuck for acquiring a warped workpiece by amplified vacuum suction shown in FIG. 2.

FIG. 4 is a schematic bottom view of the chuck for acquiring a warped workpiece by amplified vacuum suction shown in FIG. 3, with the cover plate removed for clarity, showing inside parts.

FIG. 5 shows a top surface of a chuck for acquiring a warped workpiece by amplified vacuum suction, according to some embodiments of the present invention, configured for acquiring and flattening different sizes of substantially rectangular workpieces.

FIG. 6 is the bottom view of a chuck for acquiring a warped workpiece by amplified vacuum suction, according to some embodiments of the present invention, with the bottom body and cover removed.

FIG. 7 is the top view of a peripheral section of a chuck for acquiring a warped workpiece by amplified vacuum suction, according to some embodiments of the present invention, with protrusions.

FIG. 8 is a side cross-sectional view of a chuck for acquiring a warped workpiece by amplified vacuum suction, according to some embodiments of the present invention, with ejectors for generating local vacuum.

### DETAILED DESCRIPTION OF THE INVENTION

In the following detailed description, numerous specific details are set forth in order to provide a thorough understanding of the invention. However, it will be understood by those of ordinary skill in the art that the invention may be practiced without these specific details. In other instances, well-known methods, procedures, components, modules, units and/or circuits have not been described in detail so as not to obscure the invention.

Although embodiments of the invention are not limited in this regard, discussions utilizing terms such as, for example, “processing,” “computing,” “calculating,” “determining,” “establishing”, “analyzing”, “checking”, or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium (e.g., a memory) that may store instructions to perform operations and/or processes. Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. Unless explicitly stated, the method embodiments described herein are not constrained to a particular order or sequence. Additionally, some of the described method embodiments or elements thereof can occur or be performed simultaneously, at the same point in time, or concurrently. Unless otherwise indicated, the conjunction “or” as used herein is to be understood as inclusive (any or all of the stated options).

In accordance with an embodiment of the present invention, a chuck for acquiring a warped workpiece by amplified suction is provided, according to some embodiments of the present invention. For example, the workpiece may be a silicon wafer that is to be processed for incorporation into one or more electronic components, a thin pane of glass (e.g., for incorporation into a touchscreen or display screen), or other types of substrates that may become warped during their formation or subsequent handling. Warping may exhibit concave curvature along one or two axes, convex curvature along one or two axes, or a mixture of concave and convex curvatures, such as in a wavy surface or such as a saddle. References herein to concave and convex curvatures of the workpiece refer to the surface of the workpiece that faces the top supporting surface of the chuck, and is to be acquired and held by the chuck.

Applying vacuum using a vacuum source via long pipes makes it very hard to affect a strong suction force and maintain it at the supporting surface of a chuck.

According to some aspects of the present invention a chuck for acquiring and holding a workpiece is provided that includes an internal compartment for temporarily maintaining vacuum that is aimed at providing temporal effective suction when it is desired to acquire a workpiece. The internal compartment is configured to be connected to a remote vacuum source (e.g., via a conduit), or to a vacuum generator within the chuck, as described hereinafter.

The internal compartment for temporarily maintaining vacuum may be fluidically linked via one or a plurality of conduits to a confined space within another compartment, the top wall of which serves as a chuck surface and is provided with vacuum ports. Said one or more conduits may be, each, provided with a controllable valve linked to a controller. When vacuum from the vacuum source is applied to the internal compartment (e.g., when the controller opens a valve of the conduit connecting the internal compartment to the vacuum source) vacuum may be maintained in the internal compartment.

When a workpiece is placed over the chuck surface and it is desired to acquire the workpiece, the controller opens the valve of each of the one or a plurality of valves of the conduits linking the space within the internal compartment to the space within the other compartment, and vacuum is affected causing suction forces via the vacuum ports to pull the workpiece and hold it onto the chuck surface. After that instance vacuum from the vacuum source prevails and is used for holding the workpiece on the chuck surface.

When it is desired to release the workpiece, one or more valves may be used to open and allow ambient air into the confined space beneath the chuck surface, thereby destroying the suction force and releasing the workpiece to be removed and transported away.

A chuck for acquiring and holding a workpiece, according to some embodiments of the present invention may include a plurality of vacuum ports distributed on the chuck surface. The distribution of the ports may be designed for a specific task. For example, the vacuum ports may be distributed peripherally on side-portion or portions of the chuck surface. In some other examples, the vacuum ports may be distributed across the entire chuck surface. The ports distribution may be constant or varied across the surface on which these ports are positioned.

According to some embodiments of the present invention, vacuum in the second space may be generated in the internal compartment using one or a plurality of Venturi ejectors.

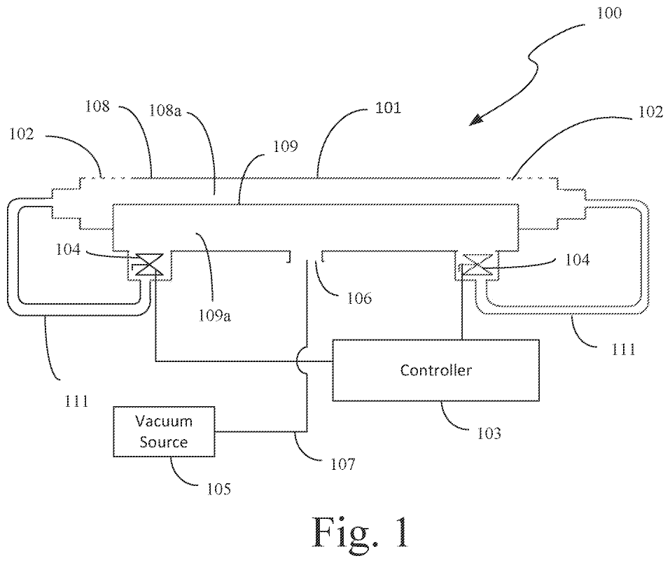

FIG. 1 schematically illustrates a cross section view of a chuck 100 for acquiring a warped workpiece by amplified vacuum suction, according to some embodiments of the present invention, configured for acquiring and flattening a warped workpiece.

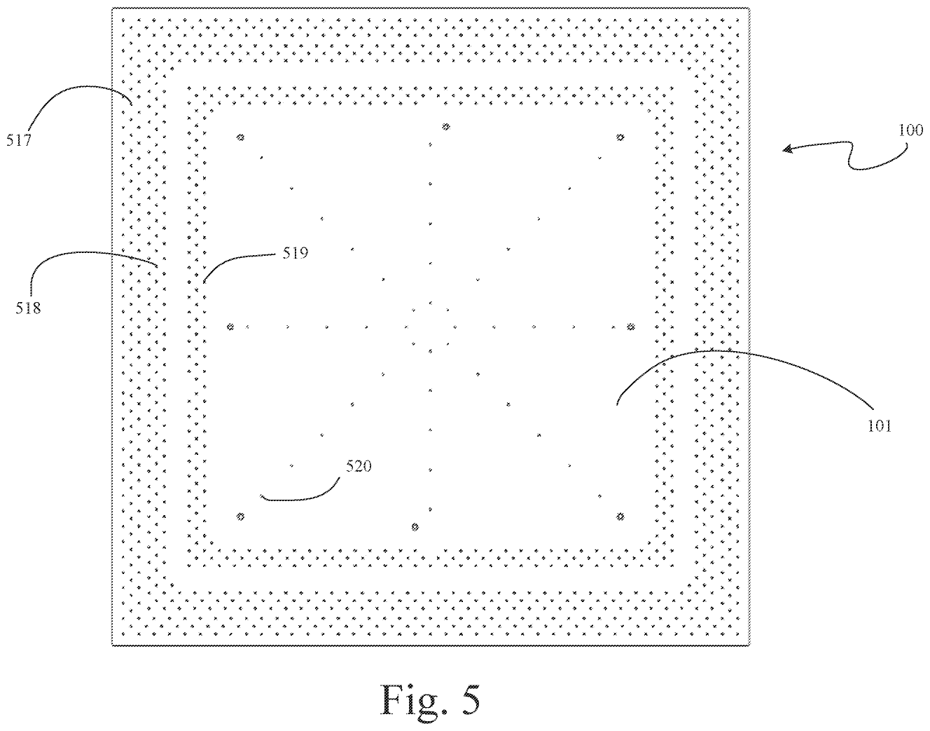

Chuck 100 may include a top supporting chuck surface 101 designed to acquire and hold a workpiece. The chuck surface may include a plurality of vacuum ports 102 distributed over the entire area of the chuck surface 101, or across specific areas of the chuck surface 101, for example peripheral areas, as shown in FIG. 1. In other embodiments of the present invention vacuum ports 102 may be distributed in other desired distribution patterns (see, for example, FIG. 5 of the present application, demonstrating three different distributions of the vacuum ports 102 over the chuck surface 101).

A first compartment 108 may define a first space 108a that is confined within the first compartment 108 with the chuck surface 101, which is configured for supporting and holding a workpiece, serving as a top wall of compartment 108. A second compartment 109, located beneath first compartment 108, defines a second space 109a. First compartment 108 and second compartment 109 are provided with one or a plurality of conduits 111, so as to fluidically connect between first space 108a and second space 109a. The second compartment 109 may include a vacuum connection port 106 for connecting to a vacuum source (for example, via a pipe linked to a remote vacuum pump).

According to some embodiments of the present invention, each of said one or a plurality of conduits 111 may include a valve 104, configured to be opened or closed by a controller 103 to allow or prevent flow, e.g., of air or other gas, in that conduit between first space 108a within first compartment 108 and second space 109a within second compartment 109.

Valve 104 may be any kind of suitable valve, for example, electro-mechanical or fluidic or of functionality based on some other working principle.

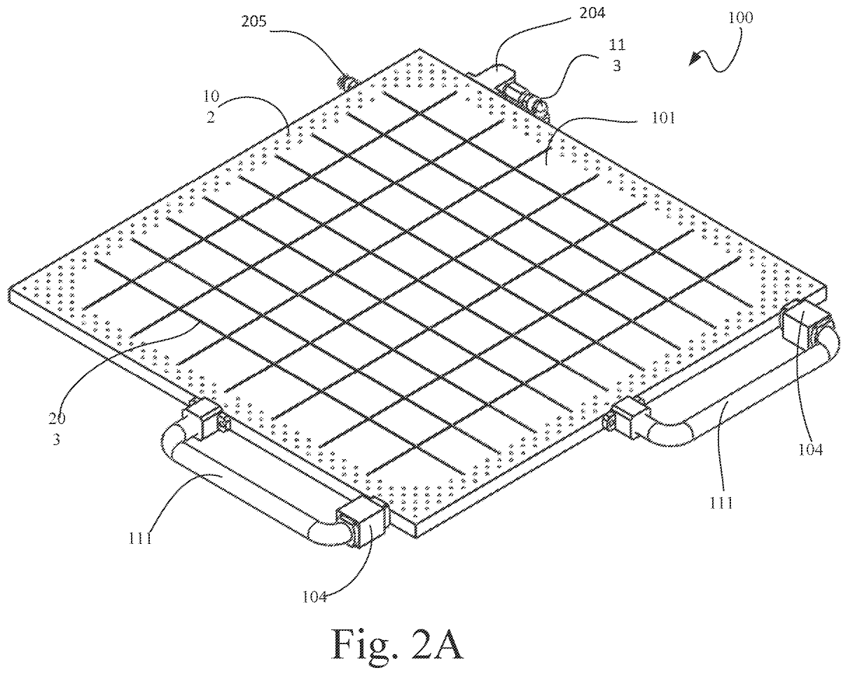

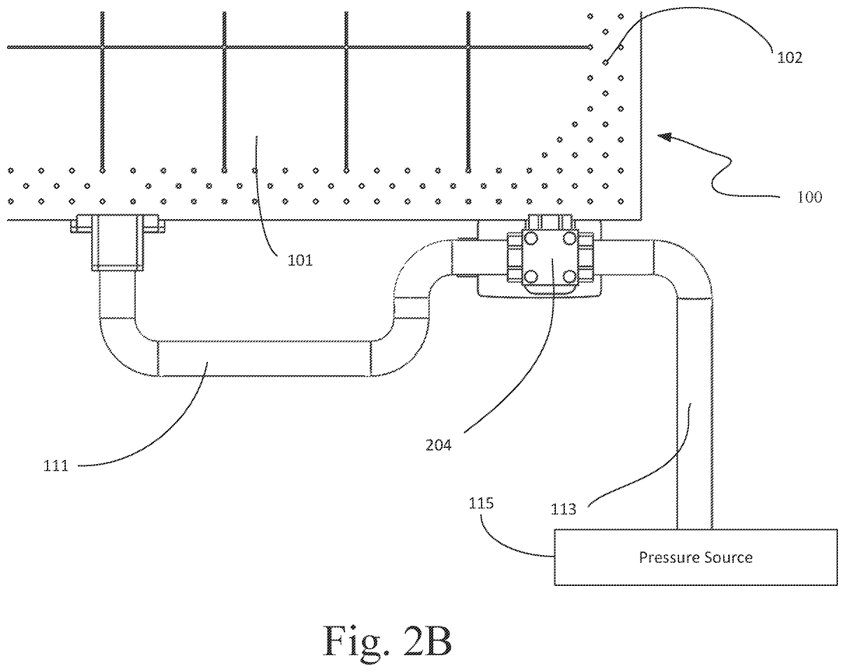

FIG. 2A shows a schematic isometric view of a chuck 100. Vacuum ports 102 are distributed over a perimeter zone of chuck surface 101, according to some embodiments of the present invention. Different distribution patterns may also be used. Two conduits 111 fluidically connect first space 108a, which is underneath chuck surface 101, to second space 109a (the internal compartment), which is underneath first space 108 (see FIG. 1). Two valves 104 are configured to open and close the two conduits 111.

According to some embodiments of the present invention, active vacuum is provided along grooves 203 that stretch over most of the central part of chuck surface 101. Grooves 203 are designed to connect to vacuum ports 102 that are located on either ends of each groove, so that when a workpiece is placed over the chuck surface the bottom surface of the workpiece practically covers some or all of the grooves, thereby affecting additional vacuum force onto the bottom of the workpiece to hold the workpiece onto chuck surface 101.

FIG. 2B shows a part of the chuck shown in FIG. 2A, detailing a three-way valve for use for the operation of an internal compartment for temporarily maintaining vacuum of the chuck.

In some embodiments of the present invention, a three-way valve 204 may be used in the operation control of the internal compartment. Conduit 111 may be equipped with a three-way valve 204, which is configured to be operated by the controller (103, see FIG. 1) to open or close conduit 111, in order to allow vacuum to accumulate within the internal compartment (when valve 204 is closed) or apply the vacuum of the internal compartment onto vacuum ports 102 (when valve 204 is open). Three-way valve 204 may be connected via conduit 113 to a pressure source 115, so that when it is desired to release the chuck grip from a held workpiece, three-way valve 204 may be operated by the controller to provide pressure to the first space 108a (of first compartment 108) via conduit 113, to release and raise the workpiece over chuck surface 101 to allow the workpiece to be picked up and transferred to a next destination. An exhaust valve 205 (see FIG. 2A) may be provided to allow evacuation of excess pressure.

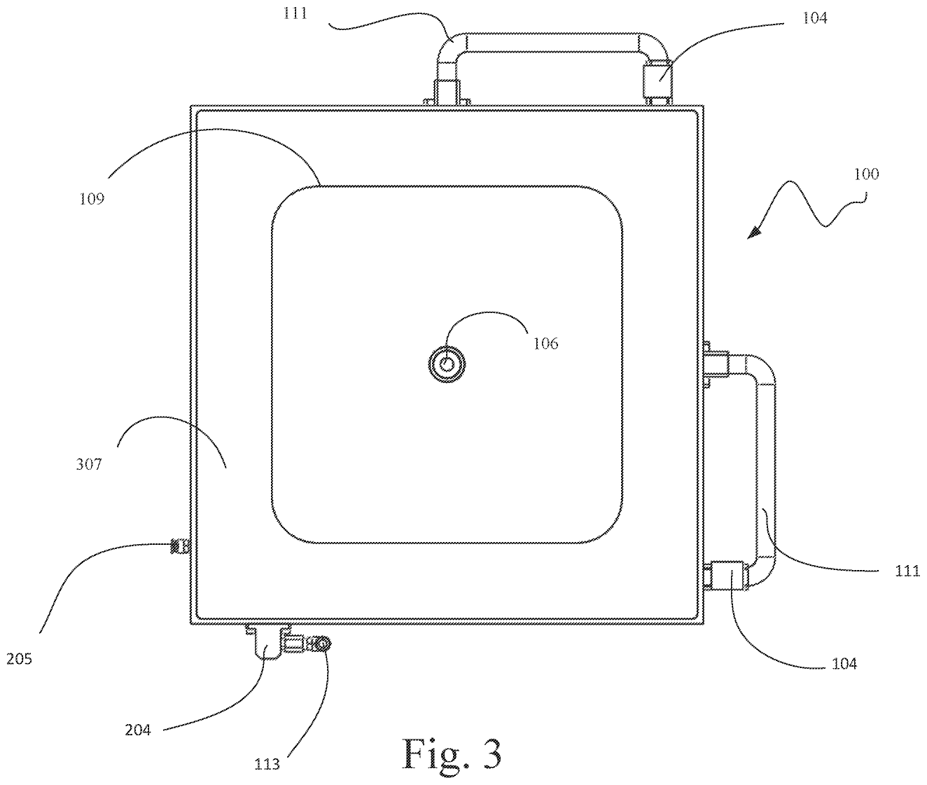

FIG. 3 shows the bottom view of chuck 100 in FIG. 2A. The bottom panel 307 of chuck 100 includes vacuum connection port 106. Bottom panel 307 may be fixed to chuck body by an adhesive, bolts, rivets, or any another fixing means.

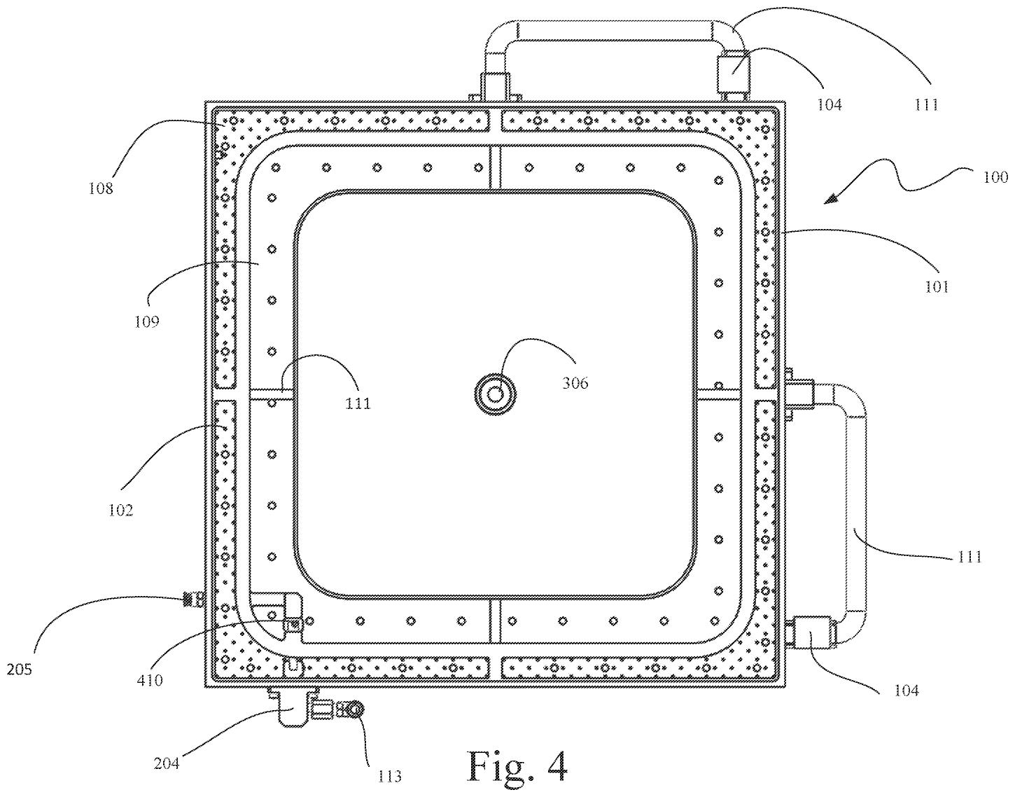

FIG. 4 is a bottom view of chuck 100 shown in FIG. 3, with bottom panel plate 307 removed for clarity, revealing inside details of the chuck surface 101 as seen from underneath.

First compartment 108 may be enclosed beneath chuck surface 101 and vacuum ports 102 and surround the internal compartment (second compartment 109). The second compartment 109 may be pumped out of air by a vacuum pump connected to vacuum connection port 306 and maintain in controlled fluidical communication with first space 108 via conduits 111 and valves 104 operated by the controller.

According to some embodiment of the present invention, the chuck surface may be configured to support different sizes of workpieces. FIG. 5 is a top view of a chuck with chuck surface 101 that can acquire and flatten rectangular workpieces of three different sizes. To achieve this chuck surface is designed to present three sets of vacuum ports arranged in concentric strips. Outermost strip of vacuum ports 517 surrounds juxtaposed inner strip of vacuum ports 518, with a third further inner strip of vacuum ports 519 located at a predetermined position with a strip of chuck surface without ports in between, all surrounding a central section of the chuck surface on which a sparser distribution of vacuum ports 520 is provided (e.g., rows of vacuum ports 520 emerging from a central location on chuck surface 101).

The central vacuum port arrangement (ports 520) is designed to acquire and hold a workpiece far from the edges of the workpiece-, while the outer strips with vacuum ports are designed to acquire and retain peripheral regions of the workpiece which may require additional suction to acquire and hold the workpiece (and flatten a warped workpiece, as may be presented to the chuck).

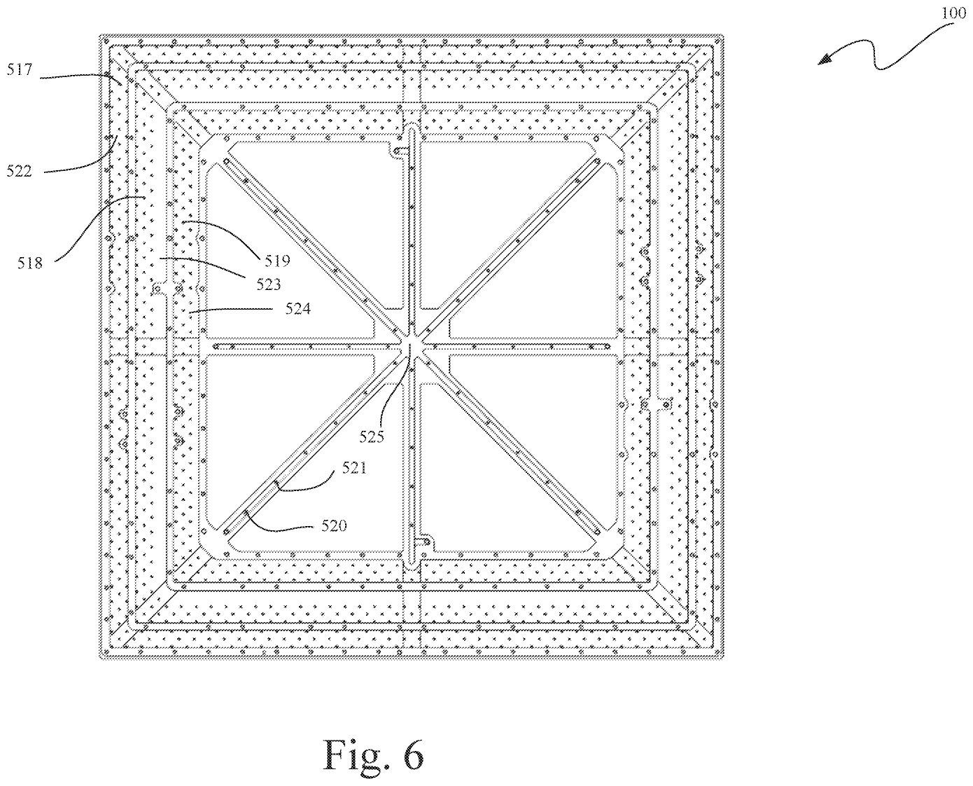

FIG. 6 shows the bottom view of chuck 100 the top of which is shown in FIG. 5. In this embodiment, a plurality of first compartments 108 defining internal spaces 108a beneath chuck surface 101, is provided, such that each strip of vacuum ports has its own internal space 108a. Each strip of vacuum ports is fluidically connected to a different instance of first compartment 108. For example, one instance 522 of first compartment is fluidically connected to and placed beneath vacuum ports 517 (see FIG. 5), another instance 523 of first compartment is fluidically connected to and placed beneath vacuum ports 518 (see FIG. 5), yet another instance 524 of first compartment is fluidically connected to and placed beneath vacuum ports 519, while yet another instance 525 of first compartment is fluidically connected to and placed beneath vacuum ports 520. Each instance 522, 523, 524, and 525 of the first compartment may be fluidically connected to the internal compartment (second space 109, see FIG. 1), via at least one or more conduits each provided with a controllable valve (e.g., valve 104, valve 205, see FIG. 1). Each of the valves may be operated by the controller separately or concurrently.

In other embodiments of the present invention the internal spaces 108a may not be concentric. For example, internal spaces 108a may be arranged such that they share a common edge, or a common corner. Other arrangements may also be considered.

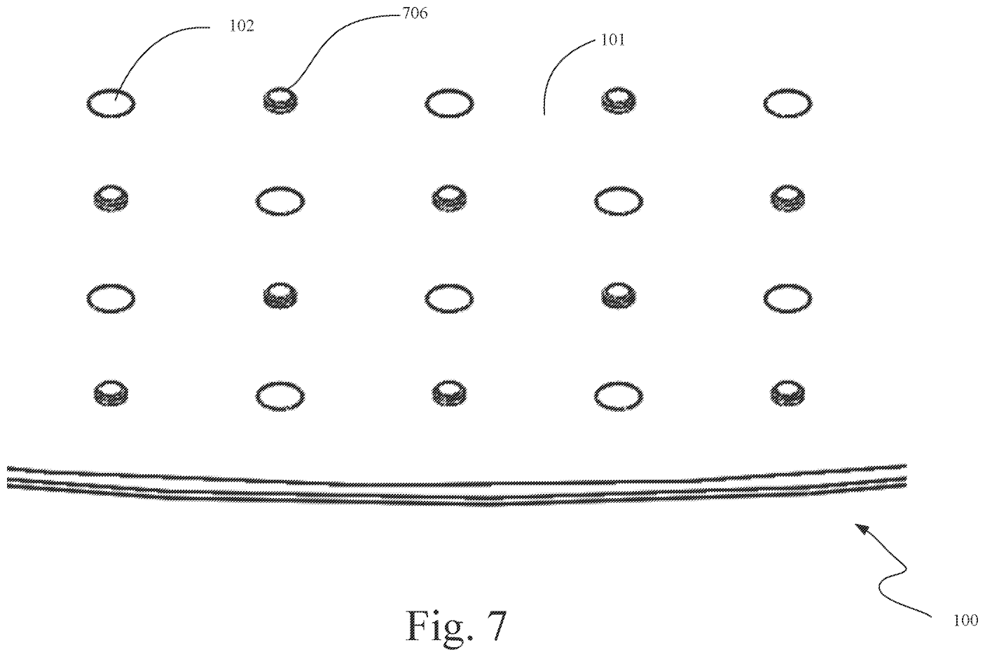

FIG. 7 shows the top view of a section of chuck surface 101 where, according to some embodiments of the present inventions, a plurality of protrusions 706 (e.g., protruding bumps, either of the same material as chuck surface 101 or of a different material) may be provided on top of chuck surface 101 to support a workpiece that is drawn to chuck surface 101 by the vacuum force exerted by the vacuum ports 102 and avoid direct contact between the workpiece and the top surface of chuck 100. Avoiding direct contact between the workpiece and the top surface of the chuck is sometimes a work requirement in some applications of the chuck such as in some cases of silicon wafer handling, e.g., in the chip manufacturing industry. Protrusions 706 may include silicon bumps, metal protrusions covered by rubber, a ceramic material, or any other material that is suitable and adapted to the specific application when using the chuck.

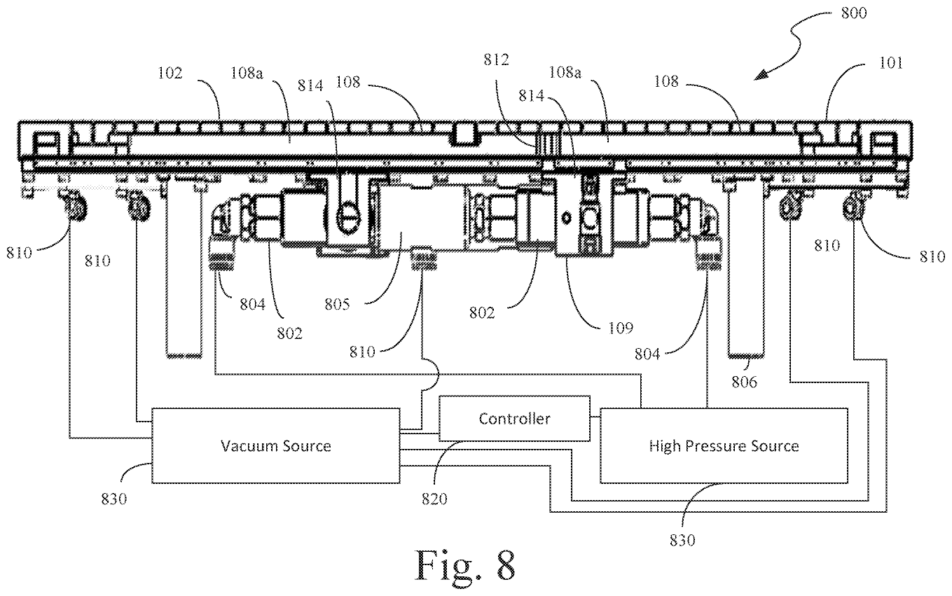

FIG. 8 is a side cross-sectional view of a chuck for acquiring a warped workpiece by amplified vacuum suction, according to some embodiments of the present invention, with ejectors for generating local vacuum.

Chuck 800 may include one or a plurality of instances of first compartment 108 (in the example of FIG. 8, there are two instances of a first compartment, separated by wall 812) beneath chuck surface 101, each of which is fluidically connected to one or a plurality of vacuum generators 802. Various types of vacuum generators may be used. In the embodiment depicted in FIG. 8, Venturi vacuum generators are used.

At second compartment 109, which in the example shown in FIG. 8 forms the vacuum inlet of the Venturi vacuum generator by the vacuum generator. The Venturi vacuum generator (sometimes called ejector) includes inlet 804 for connecting to a high-pressure source 830 to cause air or gas flow through the ejector. A vacuum inlet 814 of the ejector is fluidically connected to each instance of the first compartment 108.

The exhaust from the ejector may be stored in another compartment 805. The vacuum compartment 109 and the high-pressure compartment 805 may be fluidically linked via a flow restrictor. The vacuum compartment may be connected to a vacuum source 840 via vacuum connection port 810 which operates at a suction rate which is smaller than the suction rate of the ejector. According to some embodiments of the present invention, pillars 806 may be provided, for supporting the structure of the chuck.

Controller 820 may be provided to control the operation of any or all of the vacuum generators 802, the high-pressure source 830, the vacuum source 840, and one or more other elements of the chuck 800.

Different embodiments are disclosed herein. Features of certain embodiments may be combined with features of other embodiments. Thus, certain embodiments may be combinations of features of multiple embodiments. The foregoing description of the embodiments of the invention has been presented for the purposes of illustration and description. It is not intended to be exhaustive or to limit the invention to the precise form disclosed. It should be appreciated by persons skilled in the art that many modifications, variations, substitutions, changes, and equivalents are possible in light of the above teaching. It is, therefore, to be understood that the appended claims are intended to cover all such modifications and changes as fall within the true spirit of the invention.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A chuck for acquiring and holding a workpiece, the chuck comprising:
one or a plurality of first compartments, each defining a first space and having a wall that forms a chuck surface having a plurality of vacuum ports that are distributed on the chuck surface;
a second compartment defining a second space for internally temporarily accumulating vacuum;
one or a plurality of conduits fluidically connecting between the second compartment and each of said one or a plurality of first compartments, each of said one or a plurality of conduits having a valve which when opened allows flow through that conduit and when closed prevents flow through that conduit; and
wherein when a vacuum source is fluidically connected to the second compartment and when the valve of each of said one or more conduits is closed vacuum is temporarily accumulated in the second compartment, such that
when the valve of each of said one or more conduits is opened, the accumulated vacuum affects suction at the plurality of vacuum ports on the chuck surface to acquire and hold a workpiece.

2. The chuck according to claim 1, further comprising a controller, configured to close the valve of each of said one or more conduits, to cause vacuum to temporarily accumulate in the second compartment, and to open the valve of each of said one or more conduits to acquire and hold a workpiece on the chuck surface.

3. The chuck according to claim 1, wherein said one or a plurality of first compartments comprises a plurality of first compartments.

4. The chuck according to claim 3, wherein the controller is configured to separately control the valves of the plurality of first compartments.

5. The chuck according to claim 3, wherein the plurality of first compartments are arranged concentrically.

6. The chuck according to claim 5, wherein the vacuum ports of the first compartments are arranged in concentric strips.

7. The chuck according to claim 6, wherein at least some of the concentric strips are adjacent to one another.

8. The chuck according to claim 6, wherein at least some of the concentric strips are separated by a gap on the chuck surface.

9. The chuck according to claim 1, wherein the second compartment comprises a vacuum connection port, for connecting to an external vacuum source.

10. The chuck according to claim 1, wherein the plurality of vacuum ports is distributed on a peripheral zone of the chuck surface.

11. The chuck according to claim 1, wherein the plurality of vacuum ports is distributed on the chuck surface in one or a plurality of distribution patterns.

12. The chuck according to claim 1, wherein said one or a plurality of first compartments comprises a single compartment.

13. The chuck according to claim 1, wherein the valve of one or more of said one or a plurality of conduits is a three-way valve.

14. The chuck according to claim 13, wherein the three-way valve is configured to be connected to a pressure source to affect pressure force at the vacuum ports to release the workpiece.

15. The chuck according to claim 1, further comprising one or a plurality of protrusions on the chuck surface to prevent direct contact between the workpiece and the chuck surface.

16. A chuck for acquiring and holding a workpiece, the chuck comprising:
a housing comprising:
one or a plurality of first compartments, each defining a first space and having a wall that forms a chuck surface having a plurality of vacuum ports that are distributed on the chuck surface;
one or a plurality of vacuum generators for affecting suction in said one or a plurality of first compartments to cause suction at the plurality of vacuum ports on the chuck surface to acquire and hold a workpiece.

17. The chuck according to claim 16, wherein said one or a plurality of vacuum generators comprises one or a plurality of Venturi vacuum generators.

18. The chuck according to claim 17, wherein an exhaust port of each of the one or a plurality of Venturi vacuum generators is connected to a vacuum source.

19. The chuck according to claim 17, further comprising a controller for controlling a blow of high-pressure through said one or a plurality of Venturi vacuum generators.

20. The chuck according to claim 19, wherein the controller is further configured to control the operation of the one or a plurality of vacuum generators.
